(19) United States
(12) Patent Application Publication
(10) Pub. No.: US 2023/0140804 A1
(43) Pub. Date: May 4, 2023

(54) BATTERY PACK, ELECTRONIC DEVICE, AND ELECTRIC TOOL

(71) Applicant: MURATA MANUFACTURING CO., LTD., Kyoto (JP)

(72) Inventors: Yuta NIKAIDO, Kyoto (JP); Iori HOSHI, Kyoto (JP)

(21) Appl. No.: 18/090,980

(22) Filed: Dec. 29, 2022

Related U.S. Application Data
(63) Continuation of application No. PCT/JP2021/031910, filed on Aug. 31, 2021.

(30) Foreign Application Priority Data
Sep. 7, 2020 (JP) 2020-149544

(51) Int. Cl. H01M 50/503; H05K 1/18; H01M 50/574; H01M 50/213; H01M 50/284; H01M 50/519

(52) U.S. Cl. CPC H01M 50/503; H01M 50/213; H01M 50/284; H01M 50/519; H01M 50/574; H05K 1/18; H05K 2201/10037; H05K 2201/10272

(57) ABSTRACT

In a battery pack, a battery and a circuit board are appropriately connected. Provided is a battery pack including: an exterior case; a circuit board; a battery including a metal exterior can; and a metal member electrically connecting the battery and the circuit board, where an electrode part is provided on at least one end side of the battery, the circuit board and the electrode part are disposed to face each other, the metal member includes a board connection connected to the circuit board, an electrode connection connected to the electrode part, and a side part, the board connection is disposed to face the electrode connection with the side part interposed therebetween, and the board connection, the side part, and the electrode connection are integrally formed.

### CROSS REFERENCE TO RELATED APPLICATIONS

The present application is a continuation of PCT Application No. PCT/JP2021/031910, filed on Aug. 31, 2021, which claims priority to Japanese patent application no. JP2020-149544, filed on Sep. 7, 2020, the entire contents of which are herein incorporated by reference.

### BACKGROUND

The present application relates to a battery pack, an electronic device, and an electric tool.

Various structures for connecting a battery and a circuit board have been proposed. For example, a structure is described where a circuit board is provided with a through hole, a battery is disposed in the through hole, and the circuit board and the battery are connected with a tab interposed therebetween.

### SUMMARY

The present application relates to a battery pack, an electronic device, and an electric tool.

Because the structure described in the Background section is a structure that has a circuit board provided with a through-hole, available batteries are limited to coin-type batteries. In addition, the mounting area of the circuit board is significantly reduced.

Accordingly, the present application provides a battery pack that has a configuration capable of appropriately connecting a battery that is larger in size than a coin-type battery and a circuit board, and an electronic device and an electric tool with the battery pack used according to an embodiment.

In an embodiment, the present application provides a battery pack including: an exterior case; a circuit board; a battery including a metal exterior can; and a metal member electrically connecting the battery and the circuit board, where an electrode part is provided on at least one end side of the battery, the circuit board and the electrode part are disposed to face each other, the metal member includes a board connection connected to the circuit board, an electrode connection connected to the electrode part, and a side part, the board connection is disposed to face the electrode connection with the side part interposed therebetween, and the board connection, the side part, and the electrode connection are integrally formed.

According to t an embodiment, the battery and the circuit board can be appropriately connected. It is to be noted that the contents of the present application are not to be construed as being limited by the effects illustrated in this specification.

### BRIEF DESCRIPTION OF THE FIGURES

FIG. 1 is a diagram referred to in the description of problems to be considered in an embodiment.

FIG. 2 is an exploded perspective view of the battery pack according to an embodiment.

FIG. 3 is a perspective view of a battery unit of a battery pack according to an embodiment.

FIG. 4 includes view A-C; where view A is a front view and a side view of a circuit board according to an embodiment; where view B is additionally a perspective view, a front view, and a side view of a bus bar according to an embodiment; and where view C is additionally perspective views of bus bars connected to a circuit board according to an embodiment respectively as viewed from one side and the opposite side of the circuit board.

FIG. 5 is an enlarged view of a part illustrating a circuit board and batteries connected by bus bars according to an embodiment.

FIG. 6 includes views A to D which are diagrams for illustrating a modification example of a bus bar.

FIG. 7 includes views A to C which are diagrams for illustrating a modification example of a bus bar.

FIG. 8 includes views A to C which are diagrams for illustrating a modification example of a bus bar.

FIG. 9 includes views A to C which are diagrams for illustrating a modification example of a bus bar.

FIG. 10 is a diagram for illustrating a modification example of a bus bar.

FIG. 11 is a diagram for illustrating a modification example of a bus bar.

FIG. 12 includes views A to C which are diagrams for illustrating a modification example of a bus bar.

FIG. 13 is a diagram for illustrating a modification example of a bus bar.

FIG. 14 is a diagram for illustrating a modification example of a bus bar.

FIG. 15 includes views A to C which are diagrams for illustrating a modification example of a bus bar.

FIG. 16 is a diagram for illustrating a modification example of a bus bar.

FIG. 17 is a diagram for illustrating a modification example of a bus bar.

FIG. 18 is a diagram for illustrating an application example.

FIG. 19 is a diagram for illustrating an application example.

FIG. 20 is a diagram for illustrating an application example.

### DETAILED DESCRIPTION

Hereinafter, one or more embodiments will be described in further detail including with reference to the drawings. Preferred specific examples of the present application are described below, the contents of which are not to be considered limiting to the present application. It is to be noted that the members recited in the claims are not to be considered specified as members according to an embodiment. In particular, the scope of the present application is, unless otherwise described, not intended to be limited to only the dimensions, materials, and shapes of the constituent members described in the embodiments, the relative configurations thereof, and the description of directions such as upward, downward, leftward, and rightward directions, which are considered by way of illustrative example only. It is to be noted that sizes, positional relationships, and the like of the members illustrated in the respective drawings may be exaggerated for the clarity of description, and for preventing complicated illustrations, only some of reference numerals may be illustrated, or a part of the illustration may be simplified. Furthermore, in the following description, the same names and reference numerals represent the identical or same members, and redundant descriptions thereof will be appropriately omitted. Furthermore, for each element constituting the present application, an aspect may be employed such that one member also serves as multiple elements made of the same member, or conversely, the function of one member can be shared and achieved by a plurality of members.

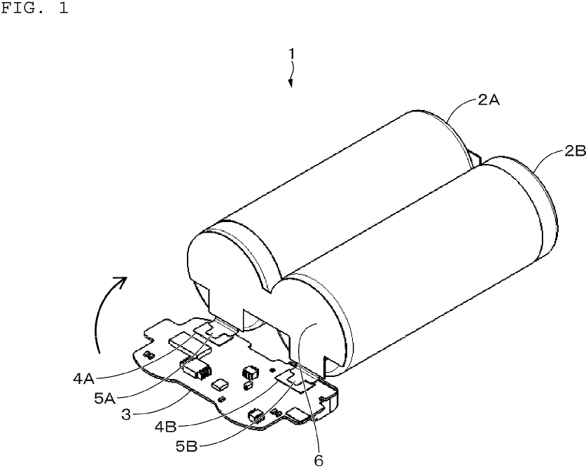

First, for facilitating understanding of the present application according to an embodiment, problems to be considered will be described. FIG. 1 is a perspective view for illustrating a configuration example of a common battery pack (battery pack 1). The battery pack 1 includes two batteries 2A and 2B. A circuit board 3 is connected to the batteries 2A and 2B. For the battery pack 1, the back surface of the circuit board 3 are provided with welded parts 4A and 4B. The welded part 4A and the electrode part of the battery 2A are connected by a metallic plate-shaped member 5A. In addition, the welded part 4B and the electrode part of the battery 2B are connected by a metallic plate-shaped member 5B. After the connection, the metallic plate-shaped members 5A and 5B are bent.

The above-described configuration requires a step of bending the metallic plate-shaped members 5A and 5B, and generates stress on the bent part of each metallic plate-shaped member. For this reason, as the process becomes complicated, there is a possibility that the bent part of each metallic plate-shaped member will be broken or cracked. In addition, for avoiding the contact between a mounted component on the circuit board 3 and the batteries 2A and 2B, it is necessary to dispose an insulating paper 6 between the circuit board 3 and the batteries 2A and 2B. In addition, a holder for holding the circuit board 3 or holding a space between the circuit board 3 and the batteries 2A and 2B is required.

Accordingly, a structure that applies no load to a metal member is desired without bending the metal member connecting the circuit board and the battery. In addition, an insulating member such as an insulating paper is preferably not provided from the viewpoint of allowing for reducing the manufacturing cost and simplifying the manufacturing process. In addition, the metal member preferably has a shape capable of achieving appropriate strength. An embodiment will be described in further detail in view of the foregoing respects.

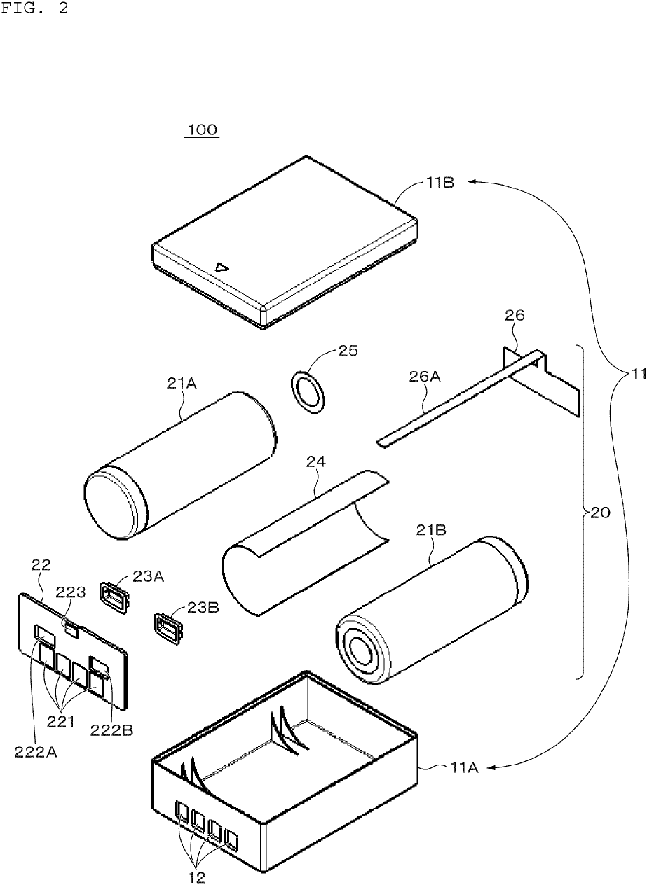

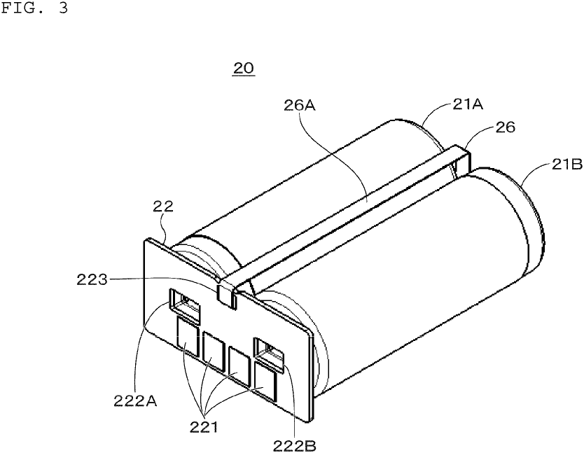

A whole configuration example of a battery pack (battery pack 100) according to an embodiment will be described with reference to FIGS. 2 and 3. FIG. 2 is an exploded perspective view of the battery pack 100, and FIG. 3 is a perspective view of a battery unit of the battery pack 100.

As shown in FIG. 2, the battery pack 100 has a case 11 as an exterior case. The case 11 is formed from, for example, a resin. The case 11 includes a box-shaped lower case 11A with an upper surface opened and a lid-shaped upper case 11B that has a rectangular shape in top view. The case 11 has a battery unit 20 housed therein. The lower case 11A has a predetermined side surface with rectangular holes 12 formed. For example, four holes 12 are formed. Terminal parts provided on a circuit board described later are exposed from the holes 12.

The battery unit 20 includes a battery 21A, a battery 21B, a circuit board 22, a bus bar 23A and a bus bar 23B, which are examples of metal members, an insulating paper 24, a ring-shaped insulating paper 25, and a relay connection member 26.

The batteries 21A and 21B are, for example, lithium ion batteries. The battery 21A and the battery 21B are, for example, batteries including electrode parts (positive electrode or negative electrode) at both end surfaces and including cylindrical metal exterior cans. According to the present embodiment, the batteries 21A and 21B are arranged so as to differ in polarity at adjacent ends.

The circuit board 22 is a board on which an IC (Integrated Circuit) or the like that performs charge/discharge control and protection control for the batteries 21A and 21B is mounted. Examples of the protection control include a protection function for preventing overcharge and overdischarge. The circuit board 22 has a predetermined circuit pattern and four terminal parts 221 formed, and the circuit pattern is connected to an appropriate terminal part. According to the present embodiment, the circuit board 22 has a rectangular shape, but may have another shape.

The bus bar 23A is a member that connects the circuit board 22 and a negative electrode terminal provided on one end side of the battery 21A. In addition, the bus bar 23B is a member that connects the circuit board 22 and a positive electrode terminal provided on one end side of the battery 21B. The bus bars 23A and 23B are made of a metal member in an appropriate shape.

The insulating paper 24 is a member disposed between the batteries for the purpose of insulation between the batteries 21A and 21B. In addition, the ring-shaped insulating paper 25 is a member disposed for the purpose of insulation between the positive and negative electrodes of the battery 21A and protection against migration.

The relay connection member 26 is a metallic member that connects the positive electrode terminal of the battery 21A and the negative electrode terminal of the battery 21B. The two batteries 21A and 21B are connected in series by the relay connection member 26. In addition, the relay connection member 26 includes a thin plate-shaped relay member 26A. The relay member 26A has an end connected to the circuit board 22. As illustrated in FIG. 3, the connection site of the relay member 26A at the circuit board 22 is connected to a protection IC, and the protection IC is configured to be capable of checking the voltages of the batteries 21A and 21B.

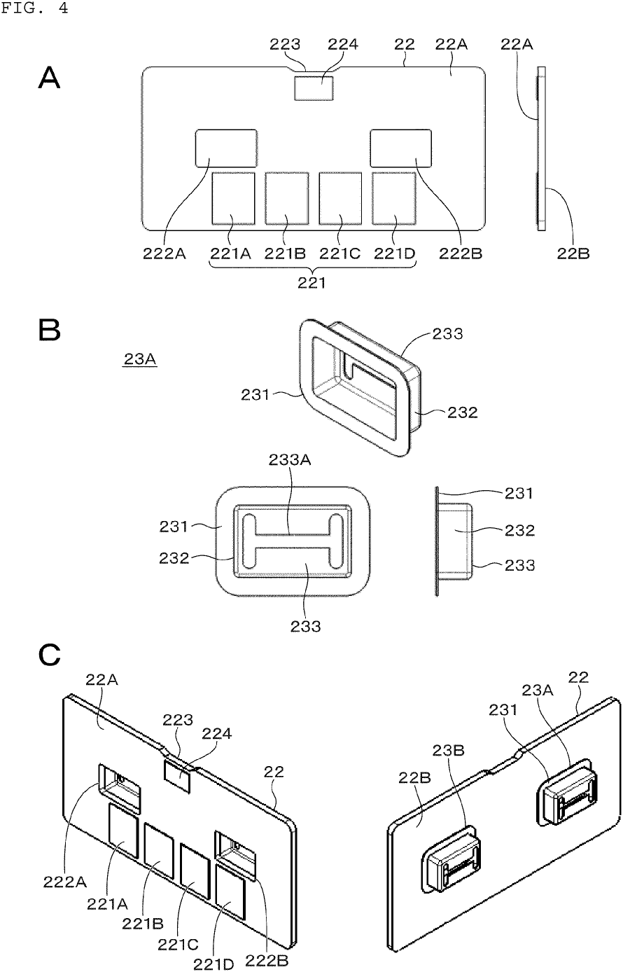

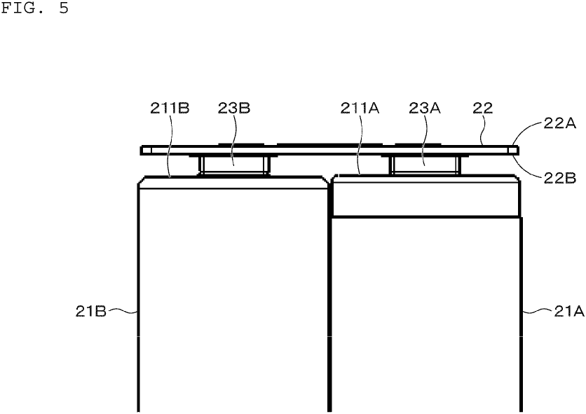

Next, exemplary shapes of the circuit board 22 and bus bars 23A and 23B will be described in detail with reference to FIGS. 4 and 5. FIG. 4A is a front view and a side view of the circuit board 22. FIG. 4B is a perspective view, a front view, and a side view of the bus bar 23A. FIG. 4C is perspective views of the bus bars 23A and 23B connected to the circuit board 22 respectively as viewed from one side and the opposite side of the circuit board 22. FIG. 5 is an enlarged view of a part illustrating the circuit board 22 and batteries 21A and 21B connected by the bus bars 23A and 23B.

As illustrated in FIG. 4A, the circuit board 22 has two rectangular holes 222A and 222B formed on the right side and left side near the center. In addition, the circuit board 22 has a notch 223 formed near the center of the upper side of the circuit board 22 in the longitudinal direction.

The circuit board 22 has one main surface 22A and a main surface 22B on the side opposite to the main surface 22A. The main surface 22A is provided with the above-described terminal parts 221 (terminal parts 221A to 221D). In addition, the main surface 22A is provided with a terminal part 224. The vicinity of the tip of the relay member 26A of the relay connection member 26 led through the notch 223 is connected to the terminal part 224.

Next, a configuration example of the bus bar 23A will be described with reference to FIG. 4B. It is to be noted that although the bus bar 23A will be described herein, the bus bar 23B has the same configuration as the bus bar 23A.

The bus bar 23A has a substantially quadrangular prism shape as a whole. Specifically, the bus bar 23A has a frame-shaped flange 231 on one end side. The flange 231 is an example of a board connection connected to the circuit board 22. As illustrated in FIG. 4C, for example, the flange 231 is solder-joined by reflow to the vicinity of the edge of the hole 222A in the main surface 22B of the circuit board 22.

In addition, a protrusion 232 in a quadrangular prism shape is formed from the vicinity of the inner peripheral edge of the flange 231. The protrusion 232 has a rectangular sectional shape (sectional shape in the case of cutting the protrusion 232 along a plane that is substantially parallel to the extending direction of the flange 231). It is to be noted that the rectangular shape means a rectangular shape or a substantially rectangular shape. For example, if a corner is chamfered, the chamfered corner is as one corner. The protrusion 232 has four side parts corresponding to side surfaces and an end surface. According to an embodiment, side-part plates are disposed on all of the side parts, and an end-surface plate is disposed on the end surface. The side-part plates and the end-surface plate are, for example, metallic plate-shaped members. The end-surface plate disposed on the end surface of the protrusion 232 functions as an electrode connection 233. The flange 231 described above is extended perpendicularly from the side parts of the protrusion 232, and is disposed to face the electrode connection 233 with the side parts of the protrusion 232 interposed therebetween. In addition, the side parts of the protrusion 232 are erected substantially perpendicular to the electrode connection 233 from the peripheral edge (inner peripheral edge) of the flange 231. The electrode connection 233 is connected to a negative electrode terminal 211A of battery 21A by welding such as resistance welding or laser welding. According to an embodiment, the part between the flange 231 of the bus bar 23A and the electrode connection 233 has a quadrangular prism shape. In addition, for the bus bar 23A, the flange 231, the side parts of the protrusion 232, and the electrode connection 233 are integrally formed.

The electrode connection 233 has a slit formed. For example, the electrode connection 233 has a slit 233A formed to have an H-shape. The flange 231 of the bus bar 23B is solder-joined to the main surface 22B of the circuit board 22. In addition, the electrode connection of bus bar 23B is welded to a positive electrode terminal 211B of the battery 21B.

As illustrated in FIG. 5, the circuit board 22 is opposed to face and the negative electrode terminal 211A of the battery 21A and the positive electrode terminal 211B of the battery 21B. The circuit board 22 and the negative electrode terminal 211A are connected by the bus bar 23A. The circuit board 22 and the positive electrode terminal 211B are connected by the bus bar 23B.

The battery pack 100 described above has, for example, the following operational effects.

The circuit board 22 and the batteries 21A and 21B are connected by the bus bars 23A and 23B in the protruded shapes, thereby allowing a space to be provided between the circuit board 22 and the electrode parts of the batteries 21A and 21B, and allowing both to be prevented from coming into contact with each other. Accordingly, the need to use any insulating component is eliminated, thus allowing for reducing the number of components and allowing for reducing the manufacturing cost.

In addition, the protrusions of the bus bars 23A and 23B have a quadrangular prism shape. Thus, the bus bars 23A and 23B can be adjusted to have at least certain strength. Accordingly, at the time of impact due to dropping, the bus bars 23A and 23B serve as supports, thereby allowing the circuit board 22 and the electrode parts of the batteries 21A and 21B to be prevented from coming into contact with each other.

Furthermore, the electrode connections of the bus bars 23A and 23B are provided with the slits 233A. Thus, the electrode connections can be elastically deformed. The electrode connections are elastically deformed, thereby causing the electrode connections to follow the shape of the electrode part. Thus, the adhesion between the electrode connections and the electrode parts of the batteries can be enhanced, and the generation of defective welding at the time of welding can be reduced as much as possible. In addition, the electrode connections are elastically deformed, thereby allowing the absorption of the phase shift and dimensional error between the plurality of batteries, and allowing the generation of defective welding caused by the shift and the error to be avoided as much as possible. Furthermore, the electrode connections are elastically deformed, thereby allowing the flanges to be prevented from being detached from the circuit board due to a dropping impact.

Next, modification examples of the metal member will be described. The modification examples of the metal member, described below, can be applied to the above-described bus bars 23A and 23B. It is to be noted that the identical or same members or configurations to or as the members or the configurations described in accordance with an embodiment are denoted by the same reference numerals, and redundant descriptions thereof will be appropriately omitted.

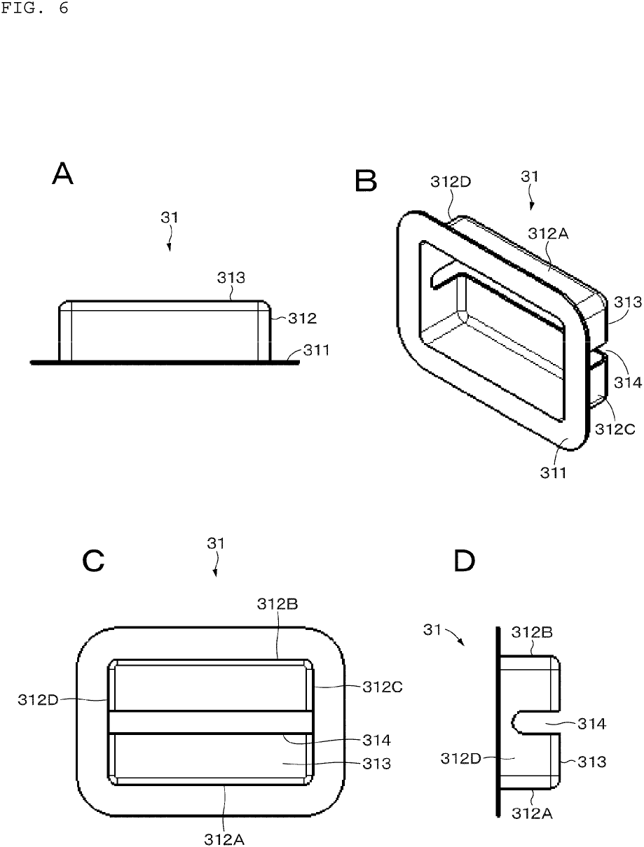

A first modification example of the metal member will be described with reference to FIGS. 6A to 6D. FIG. 6A is a side view of a bus bar (bus bar 31) according to the first modification example, FIG. 6B is a perspective view of the bus bar 31, FIG. 6C is a front view of the bus bar 31, and FIG. 6D is a side view of the bus bar 31 viewed from a direction that is different from that in FIG. 6A.

As illustrated in FIG. 6A, the bus bar 31 has a substantially quadrangular prism shape as with the bus bar 23A. The bus bar 31 has a flange 311 that functions as a board connection, and has a protrusion 312 protruding from the flange 311. The protrusion 312 has a quadrangular prism shape and has side parts 312A and 312B in the longitudinal direction and side parts 312C and 312D in the lateral direction, and a side-part plate is disposed on each side part. In addition, the protrusion 312 has an end surface, and an end-surface plate disposed on the end surface functions as the electrode connection 313. The flange 311 is disposed to face the electrode connection 313 with the side parts 312A to 312D interposed therebetween. In addition, the flange 311, the side parts 312A to 312D, and the electrode connection 313 are integrally formed.

The electrode connection 313 has a slit 314 formed therein. As illustrated in FIG. 6C, the slit 314 is, for example, a slit extending in the longitudinal direction of the electrode connection 313. In addition, the slit 314 according to the present modification example is extended from the electrode connection 313 to the side-part plates disposed on the side parts. As illustrated in FIGS. 6B and 6D, for example, the slit 314 is formed across the side-part plates disposed on the side part 312C and the side part 312D. As described above, the slit may be extended to at least parts of the side-part plates disposed on the side parts. The slit is extended to the side parts, thereby making the electrode connection more likely to be elastically deformed.

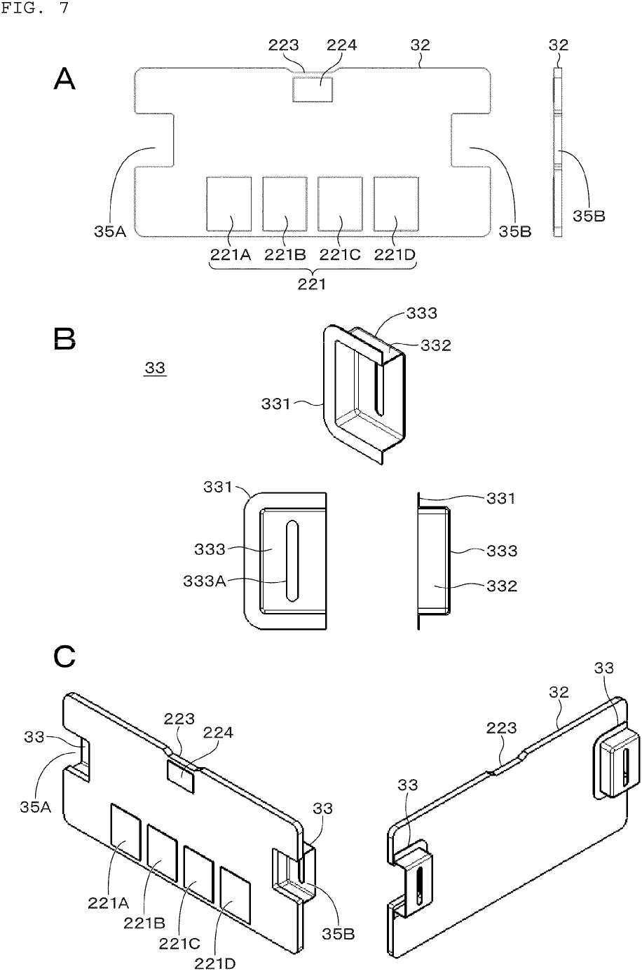

Next, a second modification example will be described with reference to FIGS. 7A to 7C. FIG. 7A is a front view and a side view of a circuit board (circuit board 32) according to the present modification example. FIG. 7B is a diagram illustrating a configuration example of a bus bar (bus bar 33) according to the present modification example. FIG. 7C is a diagram illustrating two bus bars 33 attached to the circuit board 32.

As illustrated in FIG. 7A, the circuit board 32 differs from the circuit board 22 in that the circuit board 32 has notches 35A and 35B without having the holes 222A and 222B. The notches 35A and 35B are formed respectively, for example, at the sides of the circuit board 32 in the lateral direction thereof.

The bus bars 33 differ from the bus bars 23A and 23B mainly in the shape of the flange and the shape of the protrusion. The bus bar 33 has a flange 331 formed in a C-shape. In addition, the bus bar 33 has a protrusion 332 protruded upward from the inner peripheral edge of the flange 331. The protrusion 332 has a configuration where side-part plates are disposed at the sites of three side parts among the four side parts of the protrusion 232 described in accordance with an embodiment, and has a sectional shape in a C-shape. In addition, the protrusion 332 has an electrode connection 333 that is an end-surface plate disposed on an end surface integrally connected to the three side parts. As illustrated in FIG. 7B, the electrode connection 333 has a slit 333A formed to extend in substantially the same direction as the longitudinal direction of the electrode connection 333. As illustrated in FIG. 7C, the flanges 331 of the two bus bars 33 are soldered by reflow to the respective peripheral edges of the notches 35A and 35B. The bus bars described above can also achieve the same operational effects as those of an embodiment.

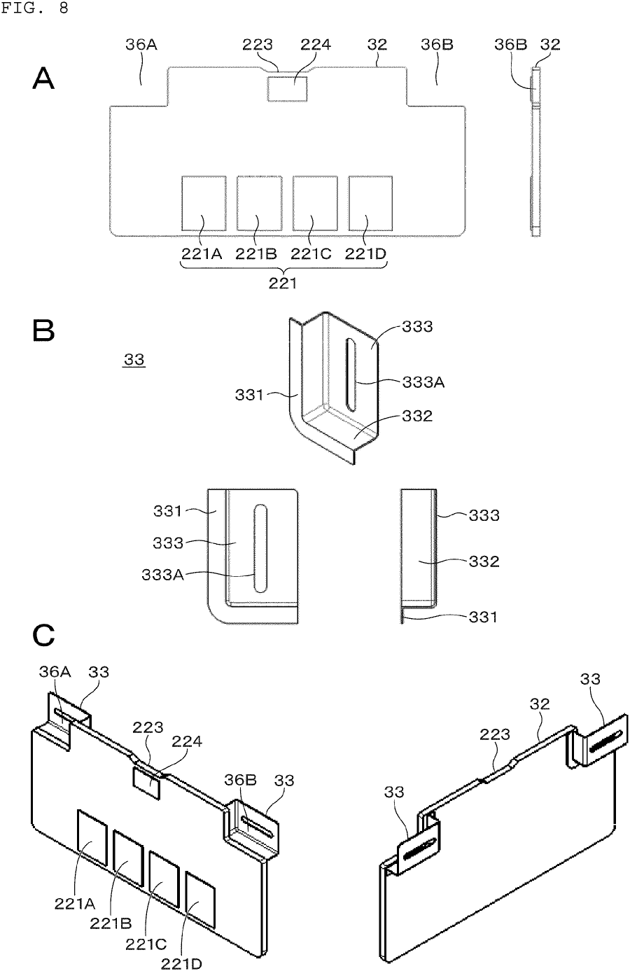

Further, as illustrated in FIG. 8B, the flange 331 of the protrusion 332 may have a configuration to form an L-shape. In this case, the protrusion 332 has a configuration where side-part plates are disposed at the sites of two adjacent side parts among the four side parts of the protrusion 232 described in accordance with an embodiment, and has a sectional shape in an L-shape. When the shape of the bus bar 33 is the shape shown in FIG. 8B, notches 36A and 36B are formed, for example, near the right and upper corners of the circuit board 32 as illustrated in FIG. 8A. Then, as illustrated in FIG. 8C, the flange 331 of the bus bars 33 are soldered by reflow to the vicinities of the peripheral edges of notches 36A and 36B.

It is to be noted that the bus bar, specifically, the protrusion preferably has an n-gonal prism shape (n = 4 in the present modification example), with prism shape is n. side-part plates disposed at sites corresponding to n/2 or more side parts, where the number of side parts of the n-gonal. In the case of a shape with side-part plates disposed at sites corresponding to less than n/2 side parts (for example, a shape with a side-part plate disposed on only one side part), the bus bar may be possibly bent by an impact due to welding or dropping. The shape with side-part plates disposed at sites corresponding to n/2 or more side parts, however, is employed, thereby making it possible to maintain a strength capable of preventing the bus bar from being bent against a load applied to the bus bar at the time of welding to the electrode part or at the time of a dropping impact.

In addition, as illustrated in FIGS. 7B and 8B, in the case of the configuration with side-part plates disposed at sites corresponding to n/2 or more side parts, the side-part plates are preferably disposed at least on the adjacent side parts. The side-part plates are disposed on the adjacent side parts, thereby allowing the force applied in one direction to be distributed, and allowing the bus bar to be prevented from bending and then falling at the time of welding or an impact applied.

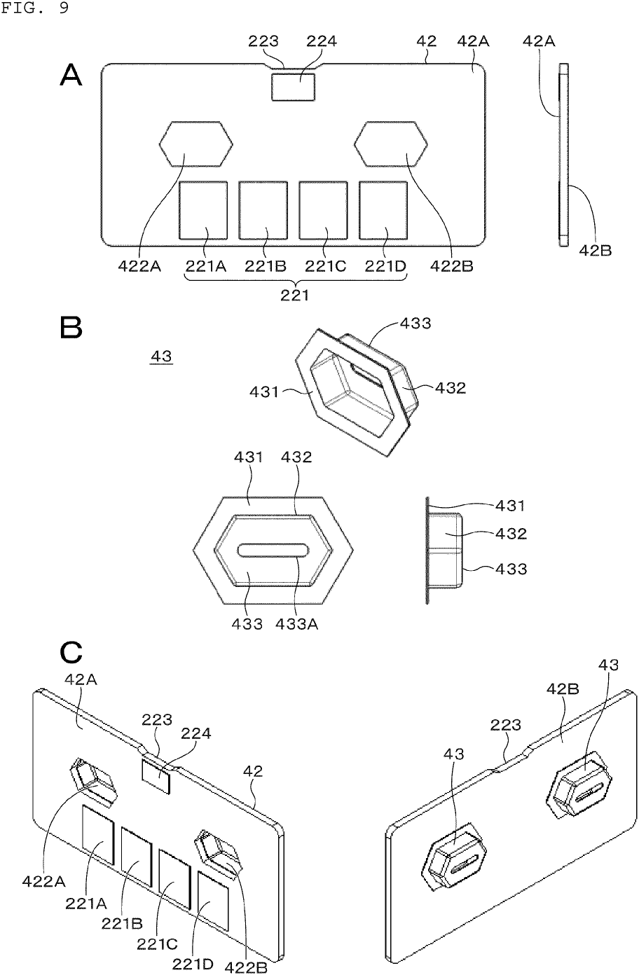

Next, a third modification example will be described with reference to FIGS. 9A to 9C. FIG. 9A is a front view and a side view of a circuit board (circuit board 42) according to the present modification example. FIG. 9B is a diagram illustrating a configuration example of a bus bar (bus bar 43) according to the present modification example. FIG. 9C is a diagram illustrating two bus bars 43 attached to the circuit board 42.

As illustrated in FIG. 9A, the circuit board 42 has hexagonal holes 422A and 422B on the right side and left side near the center. Terminal parts 221 and 224 are provided on one main surface 42A of the circuit board 42.

As illustrated in FIG. 9B, the bus bar 43 has a hexagonal flange 431. In addition, the bus bar 43 has a protrusion 432 in a hexagonal prism shape protruded with respect to the flange 431 and protruding from the inner peripheral edge of the flange 431. The protrusion 432 has six side parts, and in this example, side-part plates are disposed on all of the six side parts. The protrusion 432 has an electrode connection 433 that is an end-surface plate disposed on an end surface, and the electrode connection 433 has a slit 433A formed therein. The sectional shape of the protrusion 432 forms a hexagonal shape. In addition, the part between the flange 431 of the bus bar 43 and the electrode connection 433 has a hexagonal prism shape.

As illustrated in FIG. 9C, the bus bar 43 is solder-joined by reflow to the peripheral edge of the hole 422A in the other main surface 42B of the circuit board 42. In addition, the other bus bar 43 is solder-joined by reflow to the peripheral edge of the hole 422B in the other main surface 42B of the circuit board 42.

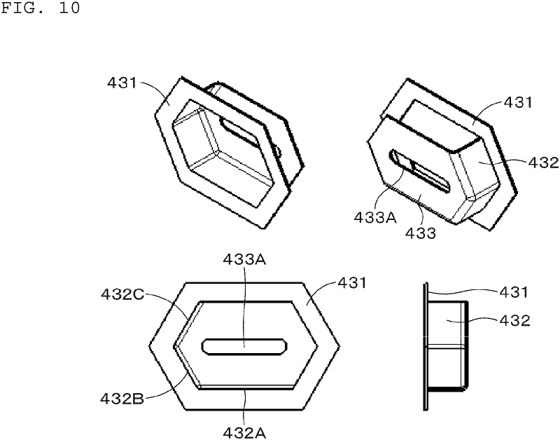

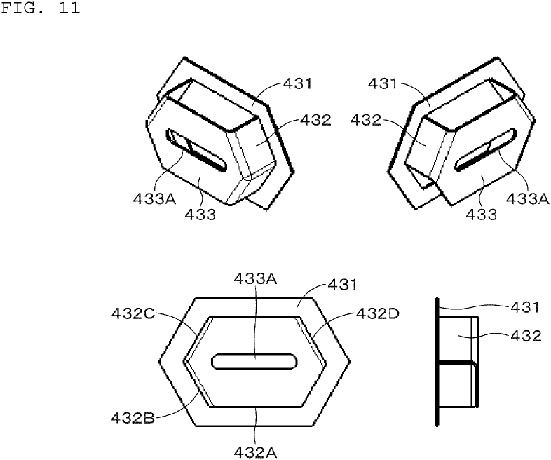

It is to be noted that although it is not necessary to dispose the side-part plates on all of the six side parts of the protrusion 432, the protrusion 432 preferably, as described above, has an n-gonal prism shape (n = 6 in the present modification example), with side-part plates disposed at sites corresponding to n/2 or more, that is, 3 or more side parts, where the number of side parts of the n-gonal prism shape is n. For example, as illustrated in FIG. 10, side-part plates are disposed on three side parts 432A, 432B, and 432C of the protrusion 432. In addition, as another example, as illustrated in FIG. 11, side-part plates are disposed on three side parts 432B, 432C, and 432D of the protrusion 432.

Furthermore, as described above, as a configuration, side-part plates are preferably disposed at least on adjacent side parts. As illustrated in FIG. 10, all of the three side parts 432A, 432B, and 432C may be adjacent, or as illustrated in FIG. 11, some side parts (432B, 432C) of the three side parts 432B, 432C, and 432D may be adjacent. In addition, the examples illustrated in FIGS. 10 and 11 are examples in which side-part plates are disposed on the three side parts, but side-part plates may be disposed on four side parts, or side-part plates may be disposed on five side parts.

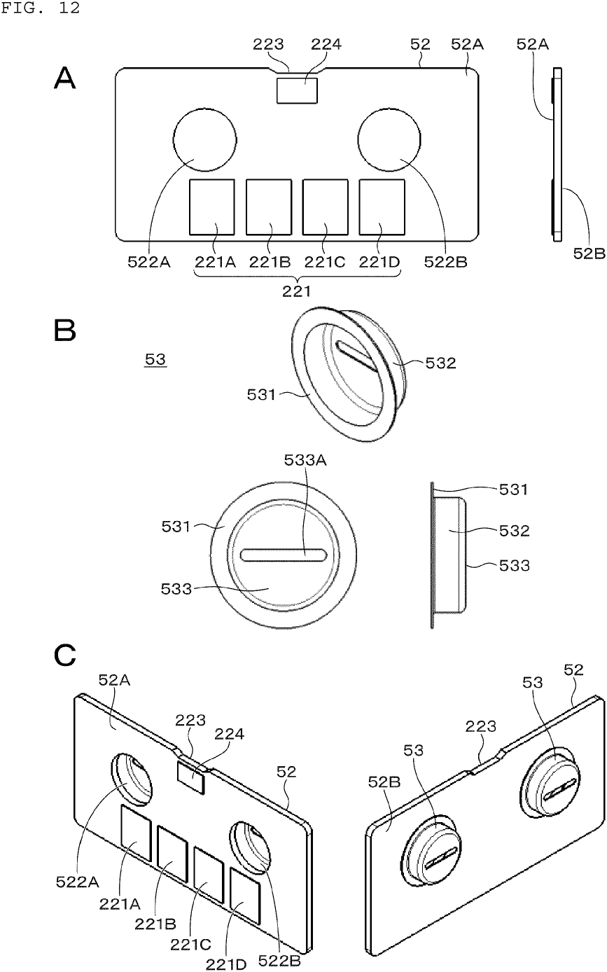

Next, a fourth modification example will be described with reference to FIGS. 12A to 12C. FIG. 12A is a front view and a side view of a circuit board (circuit board 52) according to the present modification example. FIG. 12B is a diagram illustrating a configuration example of a bus bar (bus bar 53) according to the present modification example. FIG. 12C is a diagram illustrating two bus bars 53 attached to the circuit board 52.

As illustrated in FIG. 12A, the circuit board 52 has circular holes 522A and 522B on the right side and left side near the center. Terminal parts 221 and 224 are provided on one main surface 52A of the circuit board 52.

As illustrated in FIG. 12B, the bus bar 53 has a substantially cylindrical shape as a whole. Specifically, the bus bar 53 has a circular flange 531. In addition, the bus bar 53 has a cylindrical protrusion 532 protruded with respect to the flange 531 and protruding from the inner peripheral edge of the flange 531. The protrusion 532 has a side part that serves as the side surface of the cylindrical shape, and in this example, a side-part plate is disposed over the whole side part. As described above, in the present modification example, the part between the flange 531 and the electrode connection 533 has a cylindrical shape. The protrusion 532 has the electrode connection 533 that is an end-surface plate disposed on an end surface, and the electrode connection 533 has a slit 533A formed therein.

As illustrated in FIG. 12C, the bus bar 53 is solder-joined by reflow to the peripheral edge of the hole 522A in the other main surface 52B of the circuit board 52. In addition, the other bus bar 53 is solder-joined by reflow to the peripheral edge of the hole 522B in the other main surface 52B of the circuit board 52.

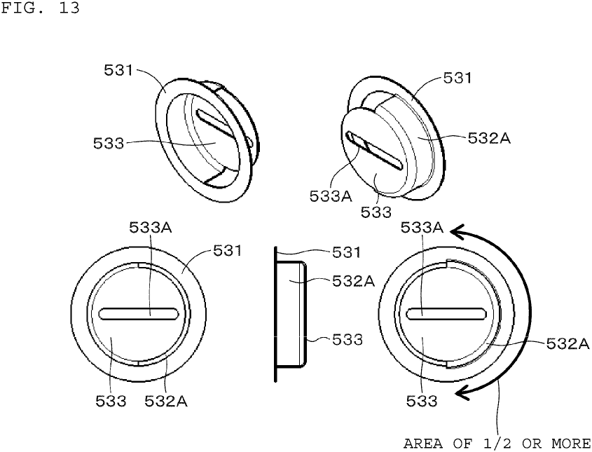

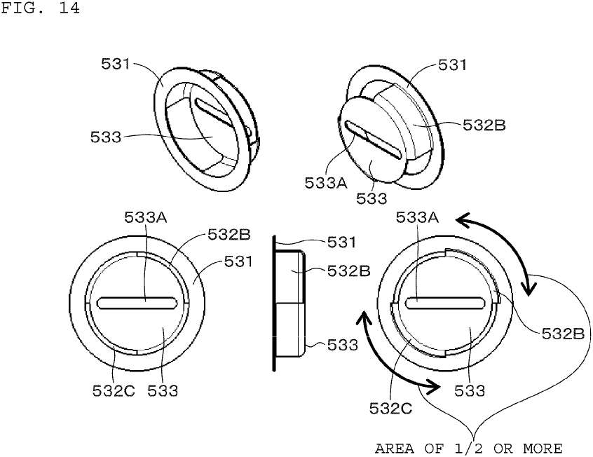

Further, although it is not necessary to dispose the side-part plate over the whole side part of the protrusion 532, the side-part plate is preferably disposed at a site corresponding to 1/2 or more of the total area of the side part. Thus, it is possible to maintain a strength capable of preventing the bus bar from being bent against a load applied to the bus bar at the time of welding to the electrode part or at the time of a dropping impact. For example, as illustrated in FIG. 13, a side-part plate 532A is disposed on a half of the side part of the protrusion 532. It is to be noted that as long as the side-part plate is disposed at a site corresponding to 1/2 or more of the total area of the side part, there is no need for a single side-part plate like the side-part plate 532A illustrated in FIG. 13, and divided side-part plates like the side-part plates 532B and 532C may be employed as illustrated in FIG. 14. In this case, for distributing the load applied to the bus bar 53 in a well-balanced manner, the side-part plates 532B and 532C are preferably disposed at positions substantially facing each other.

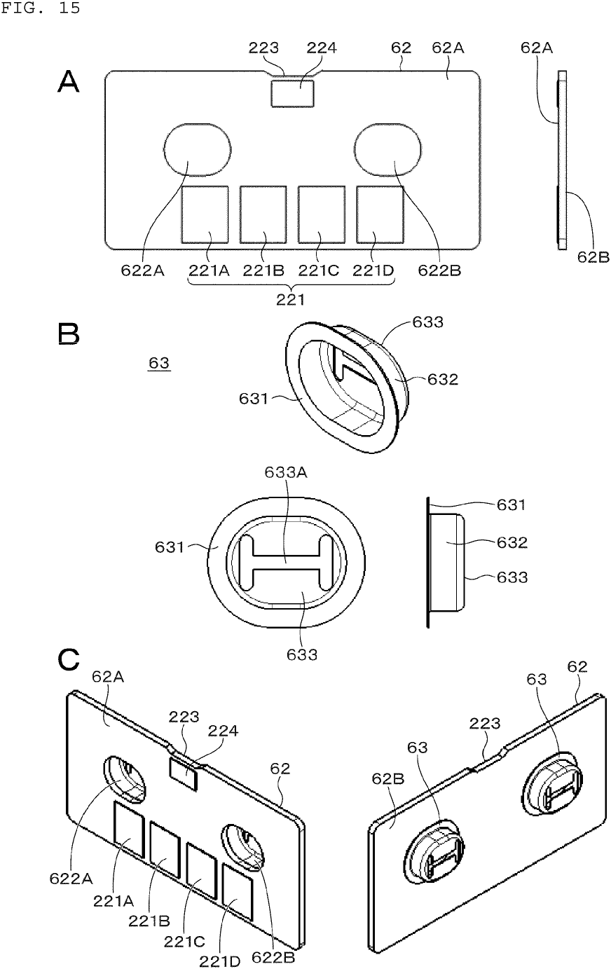

Next, a fifth modification example will be described with reference to FIGS. 15A to 15C. FIG. 15A is a front view and a side view of a circuit board (circuit board 62) according to the present modification example. FIG. 15B is a diagram illustrating a configuration example of a bus bar (bus bar 63) according to the present modification example. FIG. 15C is a diagram illustrating two bus bars 63 attached to the circuit board 62.

As illustrated in FIG. 15A, the circuit board 62 has elliptical holes 622A and 622B on the right side and left side near the center. Terminal parts 221 and 224 are provided on one main surface 62A of the circuit board 62.

As illustrated in FIG. 15B, the bus bar 63 has a substantially elliptic cylindrical shape as a whole. Specifically, the bus bar 63 has an elliptical flange 631. In addition, the bus bar 63 has a protrusion 632 in an elliptic cylindrical shape protruded with respect to the flange 631 and protruding from the inner peripheral edge of the flange 631. The protrusion 632 has a side part that serves as the side surface of the elliptic cylindrical shape, and in this example, a side-part plate is disposed over the whole side part. The protrusion 632 has an electrode connection 633 that is an end-surface plate disposed on an end surface, and the electrode connection 633 has an H-shaped slit 633A formed therein.

As illustrated in FIG. 15C, the bus bar 63 is solder-joined by reflow to the peripheral edge of the hole 622A in the other main surface 62B of the circuit board 62. In addition, the other bus bar 63 is solder-joined by reflow to the peripheral edge of the hole 622B in the other main surface 62B of the circuit board 62.

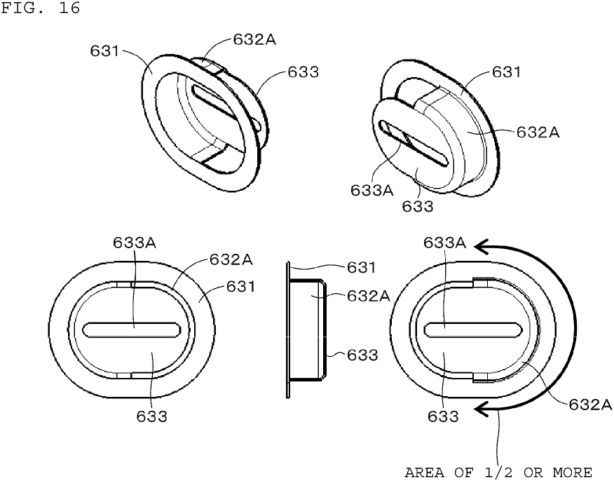

Further, although it is not necessary to dispose the side-part plate over the whole side part of the protrusion 632, the side-part plate is preferably disposed at a site corresponding to 1/2 or more of the total area of the side part. Thus, it is possible to maintain a strength capable of preventing the whole side-part plate from being bent against a load applied to the side-part plate at the time of welding to the electrode part or at the time of a dropping impact. For example, as illustrated in FIG. 16, a side-part plate 632A is disposed on a half of the side part of the protrusion 632. It is to be noted that in the case of such a configuration, the area for supporting the electrode connection 633 is reduced. Thus, for increase the bending strength of the electrode connection 633 (the strength against a force applied in a direction orthogonal to the main surface of the electrode connection 633), the area of the slit 633A may be reduced. For example, as illustrated in FIG. 16, the shape of the slit 633A may be changed from the H-shape to an elliptical shape.

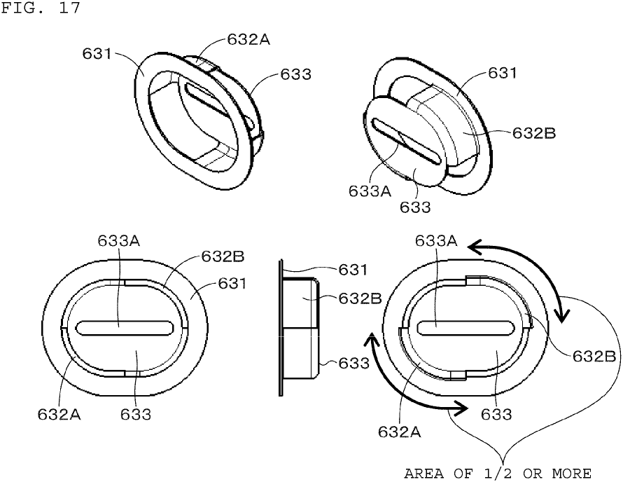

It is to be noted that as long as the side-part plate is disposed at a site corresponding to 1/2 or more of the total area of the side part, there is no need for a single side-part plate like the side-part plate 632A illustrated in FIG. 16, and divided side-part plates like the side-part plates 632B and 632C may be employed as illustrated in FIG. 17. In this case, for distributing the load applied to the bus bar 63 in a well-balanced manner, the side-part plates 632B and 632C are preferably disposed at positions substantially facing each other.

While an embodiment of the present application has been described above, the contents of the present application are not to be considered limited thereto, and it is possible to make various modifications based on technical idea of the present application.

The metal exterior can of the battery may have the cylindrical shape described in an embodiment, or may have another shape, for example, an angular shape. In the case of the angular shape, the positive electrode terminal and the negative electrode terminal may be led out from the same end. More specifically, the positive electrode terminal and the negative electrode terminal may be provided at different ends as in the embodiment, or may be provided on the same end side.

The configurations of the circuit board, bus bar, and battery unit can be appropriately changed without departing from the scope of the present application. For example, the battery unit may have three or more batteries, and three or more bus bars may be used so as to correspond to the three or more batteries.

The matters described in the above-described embodiments and modification examples can be appropriately combined. In addition, the materials, processes, and the like described in the embodiments are considered merely by way of example, and the contents of the present application are not to be considered limited to the exemplified materials or the like.

The battery pack according to the present application can be used for mounting on various electronic devices such as a wireless phone, an electric tool, an electric vehicle, or the like, or for supplying electric power thereto.

Next, a specific application example will be described. For example, the above-described battery pack can be used as a power supply for a wearable device that has the function of a portable information terminal, that is, a so-called wearable terminal. Examples of the wearable terminal include, but not to be considered limited thereto, a wristwatch-type terminal and a glasses-type terminal.

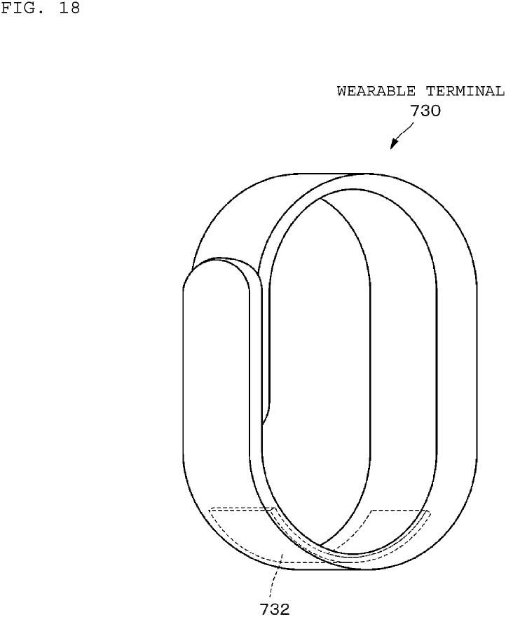

FIG. 18 shows an example of a wearable terminal that has a built-in a battery pack. As illustrated in FIG. 18, the wearable terminal 730 according to the application example is a wristwatch-type terminal, which includes therein a battery pack 732. The battery pack according to the present application can be applied as the battery pack 732. The wearable terminal 730 can be worn and then used by the user. The wearable terminal 730 may be a deformable flexible terminal.

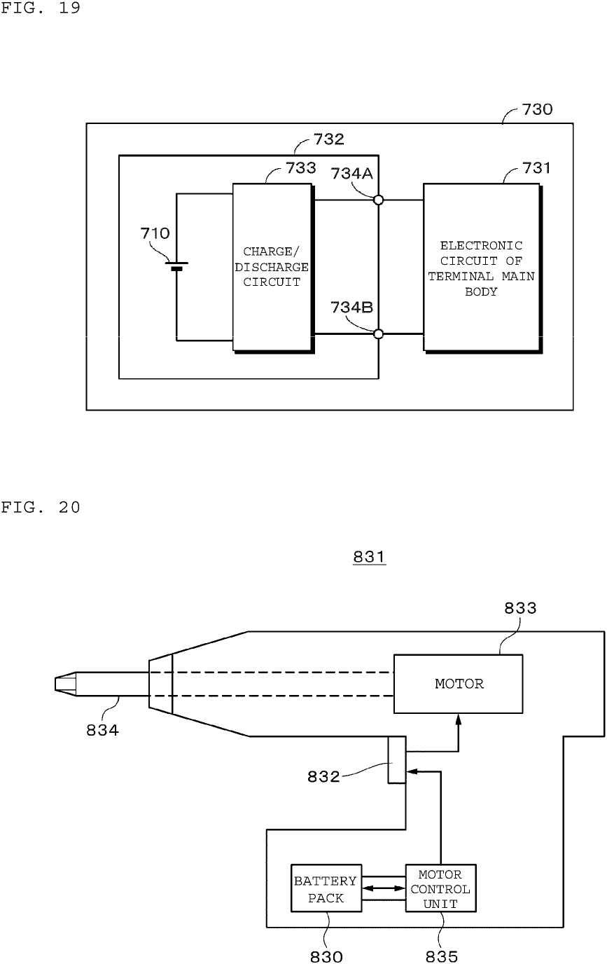

As illustrated in FIG. 19, the wearable terminal 730 according to the application example includes an electronic circuit 731 of an electronic device main body, and the battery pack 732. The battery pack 732 is electrically connected to the electronic circuit 731. The wearable terminal 730 has, for example, a configuration that allows the user to attach/detach the battery pack 732. It is to be noted that the configuration of the wearable terminal 730 is not limited thereto, and the battery pack 732 may be configured to be built in the wearable terminal 730 so that the user is not allowed to remove the battery pack 732 from the wearable terminal 730.

In the case of charging the battery pack 732, the positive electrode terminal 734A and negative electrode terminal 734B of the battery pack 732 are respectively connected to a positive electrode terminal and a negative electrode terminal of a charger (not shown). In contrast, in the case of discharging the battery pack 732 (in the case of using the wearable terminal 730), the positive electrode terminal 734A and negative electrode terminal 734B of the battery pack 732 are respectively connected to a positive electrode terminal and a negative electrode terminal of the electronic circuit 731.

The electronic circuit 731 includes, for example, a CPU, a peripheral logic unit, an interface unit, a storage unit, and the like, and controls the wearable terminal 730.

The battery pack 732 includes the battery pack according to an embodiment and a charge/discharge circuit 733 .

Next, an application example to which the battery pack according to the present application can be applied will be described. First, an example of an electric driver as an electric tool to which the present application can be applied will be schematically described with reference to FIG. 20. An electric driver 831 is provided with a motor 833 that transmits rotative power to a shaft 834 and a trigger switch 832 operated by a user. A battery pack 830 according to the present application and a motor control unit 835 are housed in a lower housing of a handle of the electric driver 831. The battery pack 830 is built in the electric driver, or detachable from the electric driver 831.

The battery pack 830 and the motor control unit 835 each may include a microcomputer (not shown), such that charge/discharge information of the battery pack 830 can be communicated with each other. The motor control unit 835 can control the operation of the motor 833, and cut off the power supply to the motor 833 at the time of abnormality such as overdischarge.

DESCRIPTION OF REFERENCE SYMBOLS

| | |
|---|---|
| 11: | Exterior case |
| 22: | Circuit board |
| 21A, 21B: | Battery |
| 23A, 23B: | Bus bar |
| 100: | Battery pack |
| 211A: | Negative electrode terminal |
| 211B: | Positive electrode terminal |
| 231: | Flange |
| 232: | Protrusion |
| 233: | Electrode connection |
| 233A: | Slit |

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A battery pack comprising:
an exterior case;
a circuit board;
a battery including a metal exterior can; and
a metal member electrically connecting the battery and the circuit board,
wherein
an electrode part is provided on at least one end side of the battery,
the circuit board and the electrode part are disposed to face each other,
the metal member includes a board connection connected to the circuit board, an electrode connection connected to the electrode part, and a side part,
the board connection is disposed to face the electrode connection with the side part interposed therebetween, and
the board connection, the side part, and the electrode connection are integrally formed.

2. The battery pack according to claim 1, wherein the side part is erected substantially perpendicular to the electrode connection from a peripheral edge of the board connection.

3. The battery pack according to claim 1, wherein the metal member is a member that has any one of a substantially polygonal prism shape, a substantially cylindrical shape, and a substantially elliptic cylindrical shape.

4. The battery pack according to claim 1, wherein the board connection is a flange extended perpendicularly from the side part.

5. The battery pack according to claim 1, wherein
a part between the board connection of and the electrode connection of the metal member has a polygonal prism shape, and
side-part plates are disposed at sites corresponding to n/2 or more sites of the side part when a sectional shape of the polygonal prism shape is an n-gonal shape.

6. The battery pack according to claim 5, wherein the side-part plates are disposed at least two adjacent sites of the side part of the metal member.

7. The battery pack according to claim 6, wherein the side-part plates are disposed at all sites of the side part.

8. The battery pack according to claim 1, wherein
a part between the board connection of and the electrode connection of the metal member has a cylindrical shape or an elliptic cylindrical shape, and
a side-part plate is disposed at a site of the side part of the metal member, the site corresponding to 1/2 or more of a total area of the side part.

9. The battery pack according to claim 8, wherein the side-part plate is disposed at all sites of the side part.

10. The battery pack according to claim 1, wherein the board connection is connected to the circuit board by solder joining.

11. The battery pack according to claim 1, wherein a slit is formed in the electrode connection.

12. The battery pack according to claim 11, wherein the slit has an H-shape.

13. The battery pack according to claim 11, wherein the slit is extended to at least a part of the side part of the metal member.

14. An electronic device comprising the battery pack according to claim 1.

15. An electric tool comprising the battery pack according to claim 1.
